(19) United States
(12) Patent Application Publication
(10) Pub. No.: US 2019/0017165 A1
(43) Pub. Date: Jan. 17, 2019

(54) Methods And Apparatus For Depositing Tungsten Nucleation Layers

(71) Applicant: Applied Materials, Inc., Santa Clara, CA (US)

(72) Inventors: Kai Wu, Palo Alto, CA (US); Sang Ho Yu, Cupertino, CA (US); Vikash Banthia, Los Altos, CA (US)

(21) Appl. No.: 16/033,866

(22) Filed: Jul. 12, 2018

Related U.S. Application Data
(60) Provisional application No. 62/532,143, filed on Jul. 13, 2017.

(51) Int. Cl. C23C 16/08; C23C 16/455

(52) U.S. Cl. CPC C23C 16/08; C23C 16/52; C23C 16/45525

(57) ABSTRACT

Methods of depositing low resistivity tungsten nucleation layers using alkyl borane reducing agents are described. Alkyl borane reducing agents utilized include compounds with the general formula BR₃, where R is a C1-C6 alkyl group. Apparatus for performing atomic layer deposition of tungsten nucleation layers using alkyl borane reducing agents are also described.

### CROSS-REFERENCE TO RELATED APPLICATIONS

This application claims priority to U.S. Provisional Application No. 62/532,143, filed Jul. 13, 2017, the entire disclosure of which is hereby incorporated by reference herein.

### TECHNICAL FIELD

Embodiments of the disclosure relate methods for depositing low-resistivity tungsten nucleation layers. More particularly, embodiments of the disclosure are directed to methods of depositing tungsten nucleation layers using alkyl borane reducing agents. Additional embodiments of the disclosure relate to apparatus for performing atomic layer deposition of tungsten nucleation layers using alkyl borane reducing agents.

### BACKGROUND

In the past two decades, tungsten (W) has been widely used in multiple levels in logic and memory devices. Typically, a process for depositing tungsten through chemical vapor deposition (CVD) provides a conformal W film growth on the substrate where it can start nucleation. This nucleation layer forms from the CVD or atomic layer deposition (ALD) reaction between WF₆ and SiH₄, or WF₆ and B₂H₆. Due to high impurities (e.g. silicon and boron) inside the nucleation film, resistivity in these nucleation layers is higher than that of W film formed by a reaction of WF₆/H₂.

To ensure good tungsten gapfill performance, typically nucleation layer thickness is required to be thicker than 20 Å for most advanced technology nodes. However, as the device scaling continues and structure CD becomes smaller and smaller, the nucleation layer contribution to contact resistance or line resistance increases, causing high Rc issue and thus lower performance on device. Moreover, traditional B₂H₆ nucleation processes result in high boron residual (greater than 20 atomic %) in the nucleation film, causing peeling issues during chemical-mechanical planarization (CMP) integration, or device performance degradation due to boron diffusion through gate on transistor.

Therefore, there is a need in the art for forming tungsten nucleation layers with lower line resistance and less residual boron.

### SUMMARY

One or more embodiments of this disclosure relate to a method of depositing a tungsten nucleation layer, the method comprising sequentially exposing a substrate to a tungsten precursor and an alkyl borane reducing agent, the tungsten precursor comprising one or more of WXₐ, where X is a halogen and a is 4 to 6, and the alkyl borane reducing agent comprises at least one compound with the general formula BR₃, where R is a C1-C6 alkyl group.

Additional embodiments of this disclosure relate to a method of depositing a tungsten nucleation layer, the method comprising sequentially exposing a substrate to a tungsten precursor and an alkyl borane reducing agent consisting essentially of one or more of trimethylborane or triethylborane, the tungsten precursor comprising a compound having the general formula WXₐ, where X is a halogen and a is 4 to 6.

Further embodiments of this disclosure relate to a processing chamber. The processing chamber comprises a susceptor assembly to support a plurality of substrates and rotate the plurality of substrate about a central axis. The susceptor assembly has a top surface with a plurality of recesses sized to hold the substrates. The processing chamber includes a gas distribution assembly having a front surface spaced from the top surface of the susceptor assembly to form a gap. The gas distribution assembly includes a plurality of gas ports and vacuum ports to provide a plurality of gas flows into the gap and a plurality of vacuum flows to remove gases from the gap. The plurality of gas ports and vacuum ports are arranged to form a plurality of process regions. Each process region is separated from adjacent process regions by a gas curtain. A controller is coupled to the susceptor assembly and the gas distribution assembly. The controller has one or more configurations. These configurations may include a first configuration to rotate the susceptor assembly about the central axis; a second configuration to provide a flow of a tungsten precursor; a third configuration to provide a flow of an alkyl borane reducing agent; or a fourth configuration to control a temperature of the susceptor assembly within a range of about 200° C. to about 500° C. The tungsten precursor comprises a compound having the general formula WXₐ, where X is a halogen and a is 4 to 6. The alkyl borane reducing agent comprises at least one compound with the general formula BR₃, where R is a C1-C6 alkyl group.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a schematic view of a processing platform in accordance with one or more embodiment of the disclosure;

FIG. 2 shows a cross-sectional view of a batch processing chamber in accordance with one or more embodiment of the disclosure;

FIG. 3 shows a partial perspective view of a batch processing chamber in accordance with one or more embodiment of the disclosure;

FIG. 4 shows a schematic view of a batch processing chamber in accordance with one or more embodiment of the disclosure;

FIG. 5 shows a schematic view of a portion of a wedge shaped gas distribution assembly for use in a batch processing chamber in accordance with one or more embodiment of the disclosure; and

FIG. 6 shows a schematic view of a batch processing chamber in accordance with one or more embodiment of the disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Embodiments of the disclosure provide methods for depositing tungsten nucleation layers. The process of various embodiments uses an atomic layer deposition (ALD) technique to provide tungsten nucleation layers.

A “substrate surface”, as used herein, refers to any portion of a substrate or portion of a material surface formed on a substrate upon which film processing is performed. For example, a substrate surface on which processing can be performed include materials such as silicon, silicon oxide, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. Substrates may have various dimensions, such as 200 mm or 300 mm diameter wafers, as well as, rectangular or square panes. In some embodiments, the substrate comprises a rigid discrete material.

“Atomic layer deposition” or “cyclical deposition” as used herein refers to a process comprising the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

In some embodiments, a tungsten deposition process advantageously achieves a low resistivity thin film. Some embodiments advantageously provide gapfill films for buried word lines for D1y in DRAM and word line for 96 pair 3D NAND. Some embodiments advantageously provide nucleation layers with low boron composition. Some embodiments advantageously provide nucleation layers that are less likely to delaminate or peel off.

In some embodiments, a hydrocarbon boron compound (e.g. alkyl boranes such as triethylborane (TEB), trimethylborane (TMB)) is used to replace conventional reducing precursors B₂H₆ or SiH₄ in the reaction with WF₆. In some embodiments, the process temperature is between 200° C. and 500° C., with pressure between 2 Torr and 100 Torr. The film deposited from this reaction contains very low boron and fluorine.

One or more embodiments of this disclosure are directed to methods of depositing a tungsten nucleation layer. The methods comprise sequentially exposing a substrate to a tungsten precursor and an alkyl borane reducing agent.

The tungsten precursor can be any suitable tungsten species that can react with the alkyl borane reducing agent. In some embodiments, the tungsten precursor comprises one or more of WXₐ, where X is a halogen and a is 4 to 6. In some embodiments, the tungsten precursor comprises one or more of W₂Cl₁₀, WCl₆, WCl₅, WF₆, or WCl₄. Those skilled in the art will recognize that tungsten (V) chloride can exist in both monomeric (WCl₅) and dimeric (W₂Cl₁₀) forms. For the purposes of this disclosure and the appended claims, WCl₅ refers to both the monomeric and dimeric forms of tungsten (V) chloride. In some embodiments, the tungsten precursor consists essentially of WCl₅. In some embodiments, the tungsten precursor consists essentially of WF₆. As used in this regard, the term “consists essentially of” means that the species in the tungsten precursor is greater than or equal to about 95%, 98% or 99% of the stated species. In some embodiments, the tungsten precursor is co-flowed with an inert, diluent or carrier gas. Suitable inert, diluent or carrier gases include, but are not limited to, argon, helium and nitrogen.

In some embodiments, the alkyl borane reducing agent comprises at least one compound with the general formula BR₃, where each R is independently a C1-C6 alkyl group. As used in this manner, the letter “C” followed by a numeral (e.g., “C4”) means that the substituent comprises the specified number of carbon atoms (e.g., C4 comprises four carbon atoms). The substituent alkyl groups can be straight chain groups (e.g. n-butyl), branched groups (e.g. t-butyl) or cyclic groups (e.g. cyclohexyl).

In some embodiments, the alkyl borane reducing agent comprises substantially no B—H bonds. In some embodiments, the alkyl borane reducing agent comprises one or more of trimethylborane, triethylborane, triisopropyl borane, tritertbutylborane, triisobutylborane or boranes with mixed alkyl groups (e.g., dimethylethylborane).

In some embodiments, the alkyl borane reducing agent consists essentially of one or more of trimethylborane or triethylborane. In some embodiments, the alkyl borane reducing agent consists essentially of trimethylborane. In some embodiments, the alkyl borane reducing agent consists essentially of triethylborane. As used in this regard, the term “consists essentially of” means that the species in the tungsten precursor is greater than or equal to about 95%, 98% or 99% of the stated species. In some embodiments, the tungsten precursor is co-flowed with an inert, diluent or carrier gas. Suitable inert, diluent or carrier gases include, but are not limited to, argon, helium and nitrogen.

In some embodiments, the substrate is not exposed to diborane (B₂H₆) or silane (SiH₄).

One or more embodiments of the method provide a tungsten nucleation layer using an atomic layer deposition (ALD) process. In a time-domain ALD process, exposure to each reactive compound is separated by a time delay to allow each compound to adhere and/or react on the substrate surface and then be purged from the processing chamber. The reactive gases are prevented from mixing by the purging of the processing chamber between subsequent exposures.

In a spatial ALD process, the reactive gases are flowed into different processing regions within a processing chamber. The different processing regions are separated from adjacent processing regions so that the reactive gases do not mix. The substrate can be moved between the processing regions to separately expose the substrate to the processing gases. During substrate movement, different portions of the substrate surface, or material on the substrate surface, are exposed to the two or more reactive compounds so that any given point on the substrate is substantially not exposed to more than one reactive compound simultaneously. As will be understood by those skilled in the art, there is a possibility that a small portion of the substrate may be exposed to multiple reactive gases simultaneously due to diffusion of the gases within the processing chamber, and that the simultaneous exposure is unintended, unless otherwise specified.

In one aspect of a time-domain ALD process, a first reactive gas (i.e., a first precursor or compound A) is pulsed into the reaction zone followed by a first time delay. A second precursor or compound B is pulsed into the reaction zone followed by a second delay. During each time delay, a purge gas, such as argon, is introduced into the processing chamber to purge the reaction zone or otherwise remove any residual reactive compound or reaction products or by-products from the reaction zone. Alternatively, the purge gas may flow continuously throughout the deposition process so that only the purge gas flows during the time delay between pulses of reactive compounds. The reactive compounds are alternatively pulsed until a predetermined film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In one aspect of a spatial ALD process, a first reactive gas and second reactive gas are delivered simultaneously to the reaction zone but are separated by an inert gas curtain and/or a vacuum curtain. The gas curtain can be combination of inert gas flows into the processing chamber and vacuum stream flows out of the processing chamber. The substrate is moved relative to the gas delivery apparatus so that any given point on the substrate is exposed to the first reactive gas and the second reactive gas.

A “pulse” or “dose” as used herein refers to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

Each process gas may be supplied under different parameters than other process gases. A process gas may be provided in one or more pulses or continuously. The flow rate of a process gases can be any suitable flow rate including, but not limited to, flow rates is in the range of about 1 to about 5000 sccm, or in the range of about 2 to about 4000 sccm, or in the range of about 3 to about 3000 sccm or in the range of about 5 to about 2000 sccm. In some embodiments, the process gasses are supplied at a flow rate in the range of 100 to 1000 sccm.

A process gas can be provided at any suitable pressure. In some embodiments, the process pressure is in the range of about 5 mTorr to about 50 Torr, or in the range of about 100 mTorr to about 40 Torr, or in the range of about 1 Torr to about 35 Torr, or in the range of about 2 Torr to about 30 Torr.

The period of time that the substrate is exposed to a process gas may be any suitable amount of time necessary to allow the formation of an adequate nucleation layer or reaction atop the substrate surface. For example, a process gas may be flowed into the process chamber for a period of about 0.1 seconds to about 90 seconds. In some time-domain ALD processes, a process gas is exposed the substrate surface for a time in the range of about 0.1 sec to about 90 sec, or in the range of about 0.5 sec to about 60 sec, or in the range of about 1 sec to about 30 sec, or in the range of about 2 sec to about 25 sec, or in the range of about 3 sec to about 20 sec, or in the range of about 4 sec to about 15 sec, or in the range of about 5 sec to about 10 sec.

In some embodiments, an inert gas may additionally be provided to the process chamber at the same time as a process gas. The inert gas may be mixed with a process gas (e.g., as a diluent gas) or be provided separately and can be pulsed or of a constant flow. In some embodiments, the inert gas is flowed into the processing chamber at a constant flow in the range of about 1 to about 10000 sccm. The inert gas may be any inert gas, for example, such as argon, helium, neon, combinations thereof, or the like.

The temperature of the substrate during deposition can be controlled, for example, by setting the temperature of the substrate support or susceptor. In some embodiments the substrate is held at a temperature in the range of about 100° C. to about 600° C., or in the range of about 150° C. to about 550° C., or in the range of about 200° C. to about 500° C., or in the range of about 250° C. to about 450° C., or in the range of about 300° C. to about 400° C.

After exposing the substrate to one process gas, the process chamber (especially in time-domain ALD) may be purged using an inert gas. (This may not be needed in spatial ALD processes as there is a gas curtain separating the reactive gases.) The inert gas may be any inert gas, for example, such as argon, helium, neon, or the like. In some embodiments, the inert gas may be the same, or alternatively, may be different from the inert gas provided to the process chamber during the exposure of the substrate to the first process gas. In embodiments where the inert gas is the same, the purge may be performed by diverting the first process gas from the process chamber, allowing the inert gas to flow through the process chamber, purging the process chamber of any excess first process gas components or reaction byproducts. In some embodiments, the inert gas may be provided at the same flow rate used in conjunction with the first process gas, described above, or in some embodiments, the flow rate may be increased or decreased. For example, in some embodiments, the inert gas may be provided to the process chamber at a flow rate of greater than 0 to about 10000 sccm to purge the process chamber. In some embodiments, the purge gas is flowed for about 5 sec. In spatial ALD, purge gas curtains are maintained between the flows of reactive gases and purging the process chamber may not be necessary. In some embodiments of a spatial ALD process, the process chamber or region of the process chamber may be purged with an inert gas.

Then the substrate is exposed to a second process gas (e.g., an alkyl borane) for a second period of time. The second process gas may react with the species on the substrate surface to create a deposited film. The second process gas may be supplied to the substrate surface at a flow rate greater than the first process gas. In one or more embodiments, the flow rate is greater than about 1 time that of the first process gas, or about 100 times that of the first process gas, or in the range of about 3000 to 5000 times that of the first process gas. The second process gas can be supplied, in time-domain ALD, for a time in the range of about 1 sec to about 30 sec, or in the range of about 5 sec to about 20 sec, or in the range of about 10 sec to about 15 sec. A process gas can be provided at any suitable pressure. In some embodiments, the process pressure is in the range of about 5 mTorr to about 50 Torr, or in the range of about 100 mTorr to about 40 Torr, or in the range of about 1 Torr to about 35 Torr, or in the range of about 2 Torr to about 30 Torr.

The process chamber may again be purged using an inert gas. The inert gas may be any inert gas, for example, such as argon, helium, neon, or the like. In some embodiments, the inert gas may be the same, or alternatively, may be different from the inert gas provided to the process chamber during previous process steps. In embodiments where the inert gas is the same, the purge may be performed by diverting the second process gas from the process chamber, allowing the inert gas to flow through the process chamber, purging the process chamber of any excess second process gas components or reaction byproducts. In some embodiments, the inert gas may be provided at the same flow rate used in conjunction with the second process gas, described above, or in some embodiments, the flow rate may be increased or decreased. For example, in some embodiments, the inert gas may be provided to the process chamber at a flow rate of greater than 0 to about 10,000 sccm to purge the process chamber. In some embodiments, the purge gas is flowed for about 5 sec.

While the embodiment of the processing method described above includes only two pulses of reactive gases, it will be understood that this is merely exemplary and that additional pulses of process gases may be used. The pulses can be repeated in their entirety or in part. The cycle can be repeated to form a tungsten nucleation layer of a predetermined thickness. In some embodiments, the cycle is repeated to form a tungsten nucleation layer with a thickness in the range of about 5 Å to about 40 Å, or in the range of about 10 Å to about 30 Å, or in the range of about 15 Å to about 20 Å.

Once the predetermined thickness has been reached, the method may optionally include further processing (e.g., bulk deposition of a tungsten metal film). In some embodiments, the further processing may be a CVD process. For example, in some embodiments, a CVD process may be performed to bulk deposit a tungsten metal layer to a target thickness.

In some embodiments, the tungsten nucleation layer comprises greater than or equal to about 95 atomic percent tungsten. In one or more embodiments, the sum of C, N, O, Si, B and halogen atoms is less than or equal to about 5 atomic percent of the tungsten nucleation layer.

In some embodiments, the tungsten nucleation layer comprises substantially no silicon atoms. In some embodiments, the tungsten nucleation layer comprises substantially no boron atoms. In some embodiments, the tungsten nucleation layer comprises less than or equal to about 10²², 10²¹, 10²⁰, 10¹⁹, or 10¹⁸ boron atoms per cm³. In some embodiments, the tungsten nucleation layer comprises substantially no halogen. In some embodiments, the tungsten precursor is a fluoride and the tungsten nucleation layer comprises substantially no fluorine. In some embodiments, the tungsten precursor comprises fluorine and the tungsten nucleation layer comprises less than or equal to about 10²⁰, 10¹⁹, or 10¹⁸ fluorine atoms per cm³.

The tungsten nucleation layer formed has a low resistivity. In some embodiments, the tungsten nucleation layer has a resistivity of less than or equal to about 140, 130, 125, 120, 110, 100, 90, 80 or 70 μΩ*cm for tungsten nucleation layers with a thickness of about 25 Å.

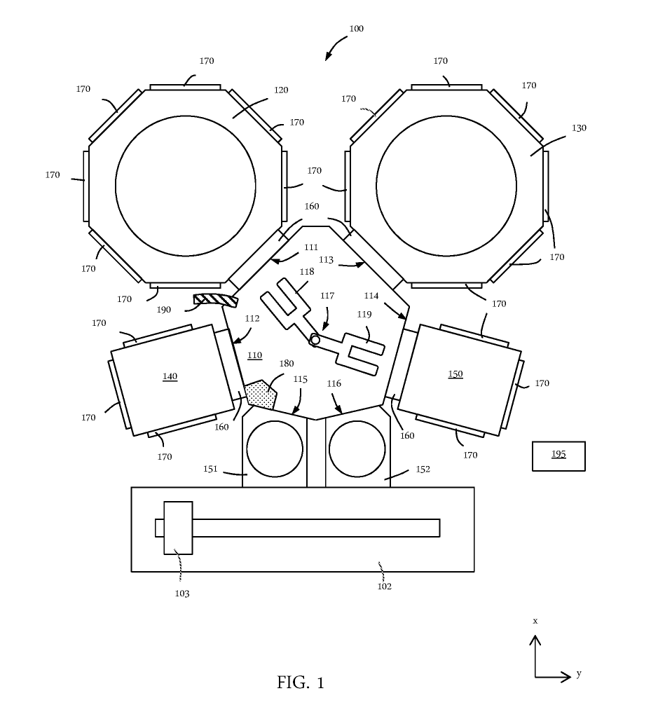

Referring to the Figures, one or more embodiments of the method are illustrated for a spatial ALD process. FIG. 1 shows a processing platform 100 in accordance with one or more embodiment of the disclosure. The embodiment shown in FIG. 1 is merely representative of one possible configuration and should not be taken as limiting the scope of the disclosure. For example, in some embodiments, the processing platform 100 has different numbers of process chambers, buffer chambers and robot configurations.

The processing platform 100 includes a central transfer station 110 which has a plurality of sides 111, 112, 113, 114, 115, 116. The transfer station 110 shown has a first side 111, a second side 112, a third side 113, a fourth side 114, a fifth side 115 and a sixth side 116. Although six sides are shown, those skilled in the art will understand that there can be any suitable number of sides to the transfer station 110 depending on, for example, the overall configuration of the processing platform 100.

The transfer station 110 has a robot 117 positioned therein. The robot 117 can be any suitable robot capable of moving a wafer during processing. In some embodiments, the robot 117 has a first arm 118 and a second arm 119. The first arm 118 and second arm 119 can be moved independently of the other arm. The first arm 118 and second arm 119 can move in the x-y plane and/or along the z-axis. In some embodiments, the robot 117 includes a third arm or a fourth arm (not shown). Each of the arms can move independently of other arms.

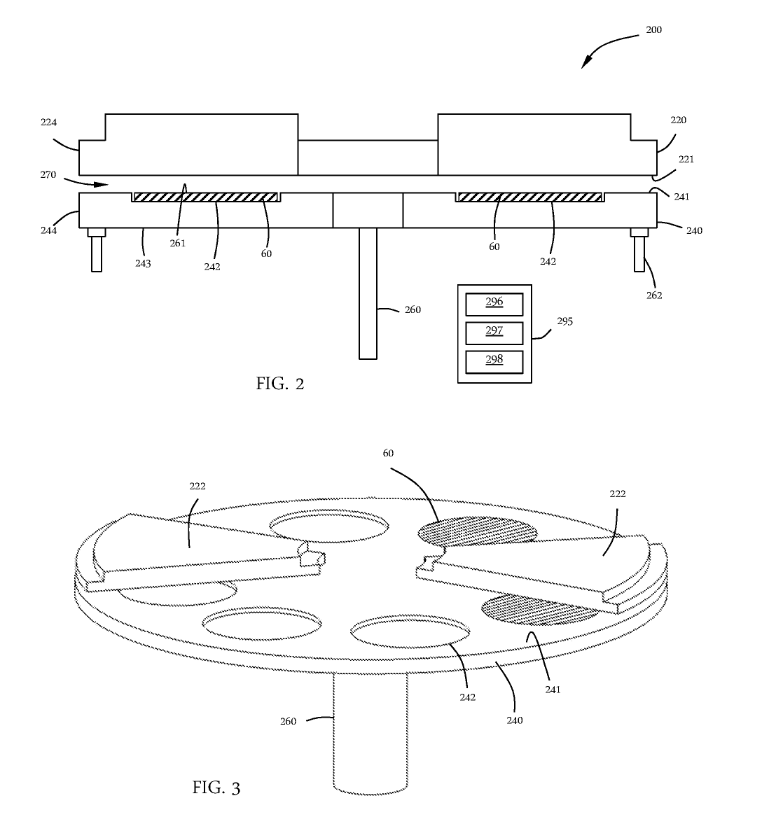

A batch processing chamber 120 can be connected to a first side 111 of the central transfer station 110. The batch processing chamber 120 can be configured to process x wafers at a time for a batch time. In some embodiments, the batch processing chamber 120 can be configured to process in the range of about four (x=4) to about 12 (x=12) wafers at the same time. In some embodiments, the batch processing chamber 120 is configured to process six (x=6) wafers at the same time. As will be understood by the skilled artisan, while the batch processing chamber 120 can process multiple wafers between loading/unloading of an individual wafer, each wafer may be subjected to different process conditions at any given time. For example, a spatial atomic layer deposition chamber, like that shown in FIGS. 2 through 6, expose the wafers to different process conditions in different processing regions so that as a wafer is moved through each of the regions, the process is completed.

FIG. 2 shows a cross-section of a processing chamber 200 including a gas distribution assembly 220, also referred to as injectors or an injector assembly, and a susceptor assembly 240. The gas distribution assembly 220 is any type of gas delivery device used in a processing chamber. The gas distribution assembly 220 includes a front surface 221 which faces the susceptor assembly 240. The front surface 221 can have any number or variety of openings to deliver a flow of gases toward the susceptor assembly 240. The gas distribution assembly 220 also includes an outer edge 224 which in the embodiments shown, is substantially round.

The specific type of gas distribution assembly 220 used can vary depending on the particular process being used. Embodiments of the disclosure can be used with any type of processing system where the gap between the susceptor and the gas distribution assembly is controlled. While various types of gas distribution assemblies can be employed (e.g., showerheads), embodiments of the disclosure may be particularly useful with spatial gas distribution assemblies which have a plurality of substantially parallel gas channels. As used in this specification and the appended claims, the term “substantially parallel” means that the elongate axis of the gas channels extend in the same general direction. There can be slight imperfections in the parallelism of the gas channels. In a binary reaction, the plurality of substantially parallel gas channels can include at least one first reactive gas A channel, at least one second reactive gas B channel, at least one purge gas P channel and/or at least one vacuum V channel. The gases flowing from the first reactive gas A channel(s), the second reactive gas B channel(s) and the purge gas P channel(s) are directed toward the top surface of the wafer. Some of the gas flow moves horizontally across the surface of the wafer and out of the process region through the purge gas P channel(s). A substrate moving from one end of the gas distribution assembly to the other end will be exposed to each of the process gases in turn, forming a layer on the substrate surface.

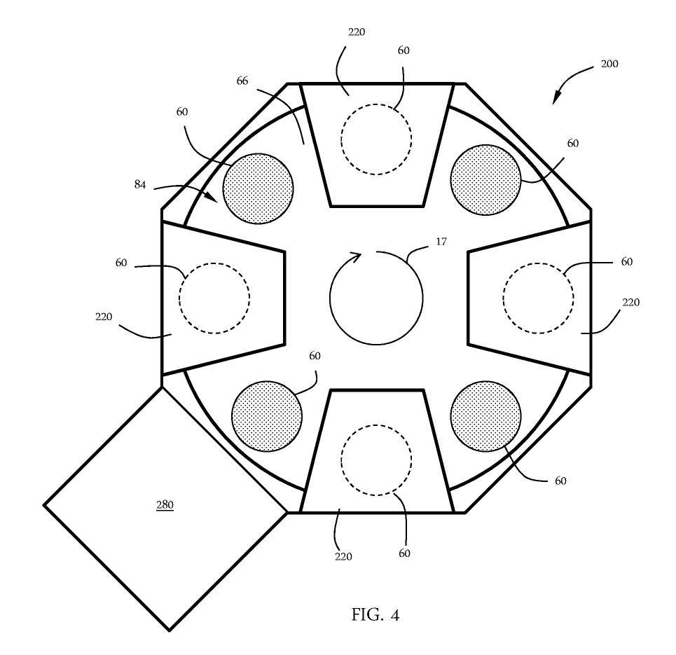

In some embodiments, the gas distribution assembly 220 is a rigid stationary body made of a single injector unit. In one or more embodiments, the gas distribution assembly 220 is made up of a plurality of individual sectors (e.g., injector units 222), as shown in FIG. 3. Either a single piece body or a multi-sector body can be used with the various embodiments of the disclosure described.

A susceptor assembly 240 is positioned beneath the gas distribution assembly 220. The susceptor assembly 240 includes a top surface 241 and at least one recess 242 in the top surface 241. The susceptor assembly 240 also has a bottom surface 243 and an edge 244. The recess 242 can be any suitable shape and size depending on the shape and size of the substrates 60 being processed. In the embodiment shown in FIG. 2, the recess 242 has a flat bottom to support the bottom of the wafer; however, the bottom of the recess can vary. In some embodiments, the recess has step regions around the outer peripheral edge of the recess which are sized to support the outer peripheral edge of the wafer. The amount of the outer peripheral edge of the wafer that is supported by the steps can vary depending on, for example, the thickness of the wafer and the presence of features already present on the back side of the wafer.

In some embodiments, as shown in FIG. 2, the recess 242 in the top surface 241 of the susceptor assembly 240 is sized so that a substrate 60 supported in the recess 242 has a top surface 61 substantially coplanar with the top surface 241 of the susceptor 240. As used in this specification and the appended claims, the term “substantially coplanar” means that the top surface of the wafer and the top surface of the susceptor assembly are coplanar within ±0.2 mm. In some embodiments, the top surfaces are coplanar within ±0.5 mm, ±0.4 mm, ±0.35 mm, ±0.30 mm, ±0.25 mm, ±0.20 mm, ±0.15 mm, ±0.10 mm or ±0.05 mm.

The susceptor assembly 240 of FIG. 2 includes a support post 260 which is capable of lifting, lowering and rotating the susceptor assembly 240. The susceptor assembly may include a heater, or gas lines, or electrical components within the center of the support post 260. The support post 260 may be the primary means of increasing or decreasing the gap between the susceptor assembly 240 and the gas distribution assembly 220, moving the susceptor assembly 240 into proper position. The susceptor assembly 240 may also include fine tuning actuators 262 which can make micro-adjustments to susceptor assembly 240 to create a predetermined gap 270 between the susceptor assembly 240 and the gas distribution assembly 220.

In some embodiments, the gap 270 distance is in the range of about 0.1 mm to about 5.0 mm, or in the range of about 0.1 mm to about 3.0 mm, or in the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The processing chamber 200 shown in the Figures is a carousel-type chamber in which the susceptor assembly 240 can hold a plurality of substrates 60. As shown in FIG. 3, the gas distribution assembly 220 may include a plurality of separate injector units 222, each injector unit 222 being capable of depositing a film on the wafer, as the wafer is moved beneath the injector unit. Two pie-shaped injector units 222 are shown positioned on approximately opposite sides of and above the susceptor assembly 240. This number of injector units 222 is shown for illustrative purposes only. It will be understood that more or less injector units 222 can be included. In some embodiments, there are a sufficient number of pie-shaped injector units 222 to form a shape conforming to the shape of the susceptor assembly 240. In some embodiments, each of the individual pie-shaped injector units 222 may be independently moved, removed and/or replaced without affecting any of the other injector units 222. For example, one segment may be raised to permit a robot to access the region between the susceptor assembly 240 and gas distribution assembly 220 to load/unload substrates 60.

Processing chambers having multiple gas injectors can be used to process multiple wafers simultaneously so that the wafers experience the same process flow. For example, as shown in FIG. 4, the processing chamber 200 has four gas injector assemblies and four substrates 60. At the outset of processing, the substrates 60 can be positioned between the gas distribution assemblies 220. Rotating 17 the susceptor assembly 240 by 45° will result in each substrate 60 which is between gas distribution assemblies 220 to be moved to a gas distribution assembly 220 for film deposition, as illustrated by the dotted circle under the gas distribution assemblies 220. An additional 45° rotation would move the substrates 60 away from the gas distribution assemblies 220. The number of substrates 60 and gas distribution assemblies 220 can be the same or different. In some embodiments, there are the same numbers of wafers being processed as there are gas distribution assemblies. In one or more embodiments, the number of wafers being processed are fraction of or an integer multiple of the number of gas distribution assemblies. For example, if there are four gas distribution assemblies, there are 4× wafers being processed, where x is an integer value greater than or equal to one. In an exemplary embodiment, the gas distribution assembly 220 includes eight process regions separated by gas curtains and the susceptor assembly 240 can hold six wafers.

The processing chamber 200 shown in FIG. 4 is merely representative of one possible configuration and should not be taken as limiting the scope of the disclosure. Here, the processing chamber 200 includes a plurality of gas distribution assemblies 220. In the embodiment shown, there are four gas distribution assemblies 220 (also called injector assemblies) evenly spaced about the processing chamber 200. The processing chamber 200 shown is octagonal; however, those skilled in the art will understand that this is one possible shape and should not be taken as limiting the scope of the disclosure. The gas distribution assemblies 220 shown are trapezoidal, but can be a single circular component or made up of a plurality of pie-shaped segments, like that shown in FIG. 3.

The embodiment shown in FIG. 4 includes a load lock chamber 280, or an auxiliary chamber like a buffer station. The load lock chamber 280 is connected to a side of the processing chamber 200 to allow, for example the substrates (also referred to as substrates 60) to be loaded/unloaded from the chamber 200. A wafer robot may be positioned in the load lock chamber 280 to move the substrate onto the susceptor.

Rotation of the carousel (e.g., the susceptor assembly 240) can be continuous or intermittent (discontinuous). In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where the carousel can pause again. Pausing between the injectors may provide time for additional processing steps between each layer deposition (e.g., exposure to plasma).

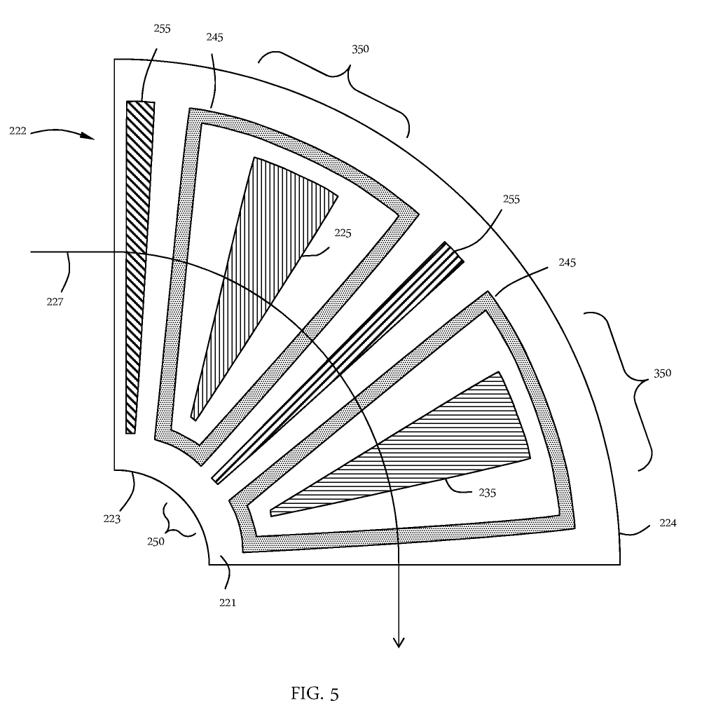

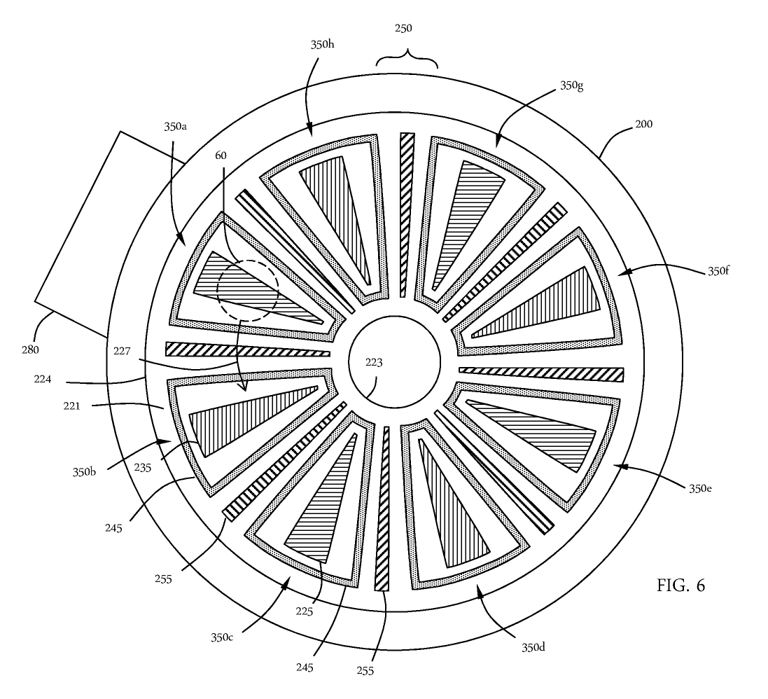

FIG. 5 shows a sector or portion of a gas distribution assembly 220, which may be referred to as an injector unit. The injector units 222 can be used individually or in combination with other injector units. For example, as shown in FIG. 6, four of the injector units 222 of FIG. 5 are combined to form a single gas distribution assembly 220. (The lines separating the four injector units are not shown for clarity.) While the injector unit 222 of FIG. 5 has both a first reactive gas port 225 and a second gas port 235 in addition to purge gas ports 255 and vacuum ports 245, an injector unit 222 does not need all of these components.

Referring to both FIGS. 5 and 6, a gas distribution assembly 220 in accordance with one or more embodiment may comprise a plurality of sectors (or injector units 222) with each sector being identical or different. The gas distribution assembly 220 is positioned within the processing chamber and comprises a plurality of elongate gas ports 225, 235, 255 and vacuum ports 245 in a front surface 221 of the gas distribution assembly 220. The plurality of elongate gas ports 225, 235, 255 and vacuum ports 245 extend from an area adjacent the inner peripheral edge 223 toward an area adjacent the outer peripheral edge 224 of the gas distribution assembly 220. The plurality of gas ports shown include a first reactive gas port 225, a second gas port 235, a vacuum port 245 which surrounds each of the first reactive gas ports and the second reactive gas ports and a purge gas port 255.

With reference to the embodiments shown in FIG. 5 or 6, when stating that the ports extend from at least about an inner peripheral region to at least about an outer peripheral region, however, the ports can extend more than just radially from inner to outer regions. The ports can extend tangentially as vacuum port 245 surrounds reactive gas port 225 and reactive gas port 235. In the embodiment shown in FIGS. 5 and 6, the wedge shaped reactive gas ports 225, 235 are surrounded on all edges, including adjacent the inner peripheral region and outer peripheral region, by a vacuum port 245.

Referring to FIG. 5, as a substrate moves along path 227, each portion of the substrate surface is exposed to the various reactive gases. To follow the path 227, the substrate will be exposed to, or “see”, a purge gas port 255, a vacuum port 245, a first reactive gas port 225, a vacuum port 245, a purge gas port 255, a vacuum port 245, a second gas port 235 and a vacuum port 245. Thus, at the end of the path 227 shown in FIG. 5, the substrate has been exposed to the first reactive gas 225 and the second reactive gas 235 to form a layer. The injector unit 222 shown makes a quarter circle but could be larger or smaller. The gas distribution assembly 220 shown in FIG. 6 can be considered a combination of four of the injector units 222 of FIG. 3 connected in series.

The injector unit 222 of FIG. 5 shows a gas curtain 250 that separates the reactive gases. The term “gas curtain” is used to describe any combination of gas flows or vacuum that separate reactive gases from mixing. The gas curtain 250 shown in FIG. 5 comprises the portion of the vacuum port 245 next to the first reactive gas port 225, the purge gas port 255 in the middle and a portion of the vacuum port 245 next to the second gas port 235. This combination of gas flow and vacuum can be used to prevent or minimize gas phase reactions of the first reactive gas and the second reactive gas.

Referring to FIG. 6, the combination of gas flows and vacuum from the gas distribution assembly 220 form a separation into a plurality of process regions 350. The process regions are roughly defined around the individual gas ports 225, 235 with the gas curtain 250 between 350. The embodiment shown in FIG. 6 makes up eight separate process regions 350 with eight separate gas curtains 250 between. A processing chamber can have at least two process regions. In some embodiments, there are at least three, four, five, six, seven, eight, nine, 10, 11 or 12 process regions.

During processing a substrate may be exposed to more than one process region 350 at any given time. However, the portions that are exposed to the different process regions will have a gas curtain separating the two. For example, if the leading edge of a substrate enters a process region including the second gas port 235, a middle portion of the substrate will be under a gas curtain 250 and the trailing edge of the substrate will be in a process region including the first reactive gas port 225.

A factory interface (shown as load lock chamber 280 in FIG. 4), which can be, for example, a load lock chamber, is shown connected to the processing chamber 200. A substrate 60 is shown superimposed over the gas distribution assembly 220 to provide a frame of reference. The substrate 60 may often sit on a susceptor assembly to be held near the front surface 221 of the gas distribution plate 220. The substrate 60 is loaded via the factory interface (e.g., load lock chamber 280) into the processing chamber 200 onto a substrate support or susceptor assembly (see FIG. 4). The substrate 60 can be shown positioned within a process region because the substrate is located adjacent the first reactive gas port 225 and between two gas curtains 250a, 250b. Rotating the substrate 60 along path 227 will move the substrate counter-clockwise around the processing chamber 200. Thus, the substrate 60 will be exposed to the first process region 350a through the eighth process region 350h, including all process regions between.

Some embodiments of the disclosure are directed to a processing chamber 200 with a plurality of process regions 350a-350h with each process region separated from an adjacent region by a gas curtain 250. For example, the processing chamber shown in FIG. 6. The number of gas curtains and process regions within the processing chamber can be any suitable number depending on the arrangement of gas flows. The embodiment shown in FIG. 6 has eight gas curtains 250 and eight process regions 350a-350h.

Referring back to FIG. 1, the processing platform 100 includes a treatment chamber 140 connected to a second side 112 of the central transfer station 110. The treatment chamber 140 of some embodiments is configured to expose the wafers to a process to treat the wafers before and/or after processing in first batch processing chamber 120. The treatment chamber 140 of some embodiments comprises an annealing chamber. The annealing chamber can be a furnace annealing chamber or a rapid thermal annealing chamber, or a different chamber configured to hold a wafer at a predetermined temperature and pressure and provide a flow of gas to the chamber.

In some embodiments, the processing platform further comprises a second batch processing chamber 130 connected to a third side 113 of the central transfer station 110. The second batch processing chamber 130 can be configured similarly to the batch processing chamber 120, or can be configured to perform a different process or to process different numbers of substrates.

The second batch processing chamber 130 can be the same as the first batch processing chamber 120 or different. In some embodiments, the first batch processing chamber 120 and the second batch processing chamber 130 are configured to perform the same process with the same number of wafers in the same batch time so that x (the number of wafers in the first batch processing chamber 120) and y (the number of wafers in the second batch processing chamber 130) are the same and the first batch time and second batch time (of the second batch processing chamber 130) are the same. In some embodiments, the first batch processing chamber 120 and the second batch processing chamber 130 are configured to have one or more of different numbers of wafers (x not equal to y), different batch times, or both.

In the embodiment shown in FIG. 1, the processing platform 100 includes a second treatment chamber 150 connected to a fourth side 114 of the central transfer station 110. The second treatment chamber 150 can be the same as the treatment chamber 140 or different.

The processing platform 100 can include a controller 195 connected to the robot 117 (the connection is not shown). The controller 195 can be configured to move wafers between the treatment chamber 140 and the first batch processing chamber 120 with a first arm 118 of the robot 117. In some embodiments, the controller 195 is also configured to move wafers between the second treatment chamber 150 and the second batch processing chamber 130 with a second arm 119 of the robot 117.

In some embodiments, a controller 295 is connected to the batch processing chamber 200. The controller 195 (in FIG. 1) can be the same controller used for the processing platform 100 or a separate controller 295 (in FIG. 2) interfaced with the controller 195. For example, a second controller 295 may be included to control the ALD process in a batch processing chamber 200.

The processing platform 100 can also include a first buffer station 151 connected to a fifth side 115 of the central transfer station 110 and/or a second buffer station 152 connected to a sixth side 116 of the central transfer station 110. The first buffer station 151 and second buffer station 152 can perform the same or different functions. For example, the buffer stations may hold a cassette of wafers which are processed and returned to the original cassette, or the first buffer station 151 may hold unprocessed wafers which are moved to the second buffer station 152 after processing. In some embodiments, one or more of the buffer stations are configured to pre-treat, pre-heat or clean the wafers before and/or after processing.

In some embodiments, the controller 195 is configured to move wafers between the first buffer station 151 and one or more of the treatment chamber 140 and the first batch processing chamber 120 using the first arm 118 of the robot 117. In some embodiments, the controller 195 is configured to move wafers between the second buffer station 152 and one or more of the second treatment chamber 150 or the second batch processing chamber 130 using the second arm 119 of the robot 117.

The processing platform 100 may also include one or more slit valves 160 between the central transfer station 110 and any of the processing chambers. In the embodiment shown, there is a slit valve 160 between each of the processing chambers 120, 130, 140, 150 and the central transfer station 110. The slit valves 160 can open and close to isolate the environment within the processing chamber from the environment within the central transfer station 110. For example, if the processing chamber will generate plasma during processing, it may be helpful to close the slit valve for that processing chamber to prevent stray plasma from damaging the robot in the transfer station.

In some embodiments, the processing chambers are not readily removable from the central transfer station 110. To allow maintenance to be performed on any of the processing chambers, each of the processing chambers may further include a plurality of access doors 170 on sides of the processing chambers. The access doors 170 allow manual access to the processing chamber without removing the processing chamber from the central transfer station 110. In the embodiment shown, each side of each of the processing chamber, except the side connected to the transfer station, have an access door 170. The inclusion of so many access doors 170 can complicate the construction of the processing chambers employed because the hardware within the chambers would need to be configured to be accessible through the doors.

The processing platform of some embodiments includes a water box 180 connected to the transfer station 110. The water box 180 can be configured to provide a coolant to any or all of the processing chambers. Although referred to as a “water” box, those skilled in the art will understand that any coolant can be used.

In some embodiments, the size of the processing platform 100 allows for the connection to house power through a single power connector 190. The single power connector 190 attaches to the processing platform 100 to provide power to each of the processing chambers and the central transfer station 110.

The processing platform 100 can be connected to a factory interface 102 to allow wafers or cassettes of wafers to be loaded into the processing platform 100. A robot 103 within the factory interface 102 can be moved the wafers or cassettes into and out of the buffer stations 151, 152. The wafers or cassettes can be moved within the processing platform 100 by the robot 117 in the central transfer station 110. In some embodiments, the factory interface 102 is a transfer station of another cluster tool.

In some embodiments, the processing platform 100 or batch processing chamber 120 is connected to a controller. The controller can be the same controller 195 or a different controller 295 (as shown in FIG. 2). The controller 295 includes central processing unit (CPU) 296, memory 297, and support circuits 298. Central processing unit 296 may be one of any form of computer processor that can be used in an industrial setting for controlling various chambers and sub-processors. Memory 297 is coupled to CPU 296 and may be one or more of readily available memory such as random access memory (RAM), read only memory (ROM), flash memory, compact disc, floppy disk, hard disk, or any other form of local or remote digital storage. Support circuits 298 are coupled to CPU 296 for supporting CPU 296 in a conventional manner. These circuits may include cache, power supplies, clock circuits, input/output circuitry, subsystems, and the like.

In some embodiments, the controller 295 includes a non-transitory computer-readable medium containing computer code that, when executed by operation of one or more computer processors, performs an operation for controlling deposition processes in the chamber. The computer code can include instruction sets for the processor to enable the processor to, inter alia, control the heaters (e.g., power, temperature and position), heat shields, susceptor assembly rotation and/or lift, valves, motors, actuators and/or the gas distribution assembly including gas flows.

The computer program code of some embodiments includes data models defining acceptable levels within the chamber for each of a plurality of gas types. The computer program code can include models or look-up tables to determine heater power settings for temperature control. In some embodiments, the computer program code includes models to determine position of one or more heat shields based on temperature feedback circuits.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

The controller 295 can be coupled to the susceptor assembly 240 and the gas distribution assembly 220 of the batch processing chamber 200 and has one or more configurations. The configurations can include, but are not limited to, a first configuration to rotate the susceptor assembly about the central axis, a second configuration to provide a flow of a tungsten precursor comprising a compound having the general formula WXₐ, where X is a halogen and a is 4 to 6, a third configuration to provide a flow of an alkyl borane reducing agent comprising at least one compound with the general formula BR₃, where R is a C1-C6 alkyl group or a fourth configuration to control a temperature of the susceptor assembly within a range of about 200° C. to about 500° C.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a tungsten nucleation layer, the method comprising sequentially exposing a substrate to a tungsten precursor and an alkyl borane reducing agent, the tungsten precursor comprising one or more of WXₐ, where X is a halogen and a is 4 to 6, and the alkyl borane reducing agent comprises at least one compound with a general formula BR₃, where R is a C1-C6 alkyl group.

2. The method of claim 1, wherein the substrate is not exposed to diborane (B₂H₆) or silane (SiH₄).

3. The method of claim 1, wherein the substrate is maintained at a temperature in the range of about 200° C. to about 500° C.

4. The method of claim 1, wherein the substrate is exposed to the tungsten precursor and alkyl borane reducing agent at a pressure in the range of about 2 torr to about 30 torr.

5. The method of claim 1, wherein the tungsten nucleation layer comprises substantially no Si.

6. The method of claim 1, wherein the tungsten nucleation layer comprises substantially no B.

7. The method of claim 1, wherein X comprises fluorine and the tungsten nucleation layer comprises substantially no F.

8. The method of claim 1, wherein the tungsten nucleation layer has a resistivity of less than or equal to about 125 μΩ*cm.

9. The method of claim 8, wherein the tungsten nucleation layer has a resistivity of less than or equal to about 100 μΩ*cm.

10. The method of claim 1, wherein the tungsten nucleation layer is deposited to a thickness in the range of about 15 Å to about 20 Å.

11. The method of claim 1, wherein the alkyl borane reducing agent comprises substantially no B—H bonds.

12. A method of depositing a tungsten nucleation layer, the method comprising sequentially exposing a substrate to a tungsten precursor and an alkyl borane reducing agent consisting essentially of one or more of trimethylborane or triethylborane, the tungsten precursor comprising a compound having a general formula WXₐ, where X is a halogen and a is 4 to 6.

13. The method of claim 12, wherein the tungsten precursor comprises WCl₅.

14. The method of claim 12, wherein the tungsten precursor comprises WF₆.

15. The method of claim 12, wherein the alkyl borane reducing agent consists essentially of trimethylborane.

16. The method of claim 12, wherein the alkyl borane reducing agent consists essentially of triethylborane.

17. The method of claim 12, wherein the substrate is maintained at a temperature in the range of about 200° C. to about 500° C.

18. The method of claim 12, wherein the tungsten nucleation layer is deposited to a thickness in the rage of about 15 Å to about 20 Å.

19. The method of claim 18, wherein the tungsten nucleation layer comprises substantially no Si, F or B and has a resistivity of less than or equal to about 100 μΩ*cm.

20. A processing chamber comprising:
a susceptor assembly to support a plurality of substrates and rotate the plurality of substrate about a central axis, the susceptor assembly having a top surface with a plurality of recesses sized to hold the substrates;
a gas distribution assembly having a front surface spaced from the top surface of the susceptor assembly to form a gap, the gas distribution assembly including a plurality of gas ports and vacuum ports to provide a plurality of gas flows into the gap and a plurality of vacuum flows to remove gases from the gap, the plurality of gas ports and vacuum ports arranged to form a plurality of process regions, each process region separated from adjacent process regions by a gas curtain; and
a controller coupled to the susceptor assembly and the gas distribution assembly, the controller having one or more configurations selected from a first configuration to rotate the susceptor assembly about the central axis, a second configuration to provide a flow of a tungsten precursor comprising a compound having a general formula WXₐ, where X is a halogen and a is 4 to 6, a third configuration to provide a flow of an alkyl borane reducing agent comprising at least one compound with a general formula BR₃, where R is a C1-C6 alkyl group or a fourth configuration to control a temperature of the susceptor assembly within a range of about 200° C. to about 500° C.
